(19) United States
(12) Patent Application Publication
(10) Pub. No.: US 2015/0329965 A1
(43) Pub. Date: Nov. 19, 2015

(54) METHODS OF LOW TEMPERATURE DEPOSITION OF CERAMIC THIN FILMS

(71) Applicant: Prasad Narhar GADGIL, Santa Clara, CA (US)

(72) Inventors: Prasad Narhar Gadgil, Santa Clara, CA (US); Peter Joseph Dusza, San Jose, CA (US)

(21) Appl. No.: 14/654,747

(22) PCT Filed: Jan. 1, 2014
(86) PCT No.: PCT/IB2014/000001

§ 371 Date: Jun. 22, 2015

Related U.S. Application Data
(60) Provisional application No. 61/745,523, filed on Dec. 21, 2012.

(51) Int. Cl. C23C 16/455; C23C 16/52

(52) U.S. Cl. CPC C23C 16/45553; C23C 16/52; C23C 16/45514

(57) ABSTRACT

A method is provided for low temperature deposition of ceramic thin films of carbides, nitrides and mixed phases such as carbo-nitrides by atomic layer deposition (ALD), nano-layer deposition (NLD), and chemical vapor deposition (CVD). The deposition chemistries employ combinations of precursors to affect thin film processes at substantially lower temperatures than current deposition processes of thin films of boron (B) carbides, nitrogen (N), nitrides, carbonitrides of silicon (Si), carbon (C), germanium (Ge), phosphorus (P), arsenic (As), oxygen (O), sulfur (S), and selenium (S) on substrates. The inventive ALD and corresponding NLD and CVD process methods provide lower temperature deposition of various thin films comprising elements from the group B, C, Si, Ge, N, P, As and O, S and Se. The reactive precursor combinations are selected on the basis of reactivity towards one another as determined by the variation of Gibb's free energy (ΔG) with respect to deposition temperature.

### CROSS-REFERENCE TO RELATED APPLICATION

This application claims priority of U.S. Provisional Patent Application Ser. No. 61/745,523 filed Dec. 21, 2012, which is incorporated herein by reference.

### FIELD OF THE INVENTION

The present invention in general relates to the deposition of thin films, and in particular to methods of low temperature deposition of ceramic thin films of carbides, nitrides and mixed phases such as carbo-nitrides by atomic layer deposition (ALD), nano-layer deposition (NLD), and chemical vapor deposition (CVD).

### BACKGROUND OF THE INVENTION

Thin films of carbides, nitrides and carbo-nitrides of silicon, germanium and boron and their mixed phases have significant and wide ranging applications in high temperature and high power electronic devices, sensors operating in harsh environments, corrosion and wear resistant coatings, and light emitting diode (LED) fabrication, etc. Prevalent methods of deposition of thin films of these materials include sputtering, physical vapor deposition (PVD), chemical vapor deposition (CVD), and atomic layer deposition (ALD), and various other deposition methods involving plasma. Of these deposition methods of thin films, however, CVD and ALD are predominant due to various advantages both of these methods offer in terms of film quality, composition, uniformity, adhesion, and large area coverage.

The CVD process that is a widely adopted in the industry is a flux dependent process. In a kinetically limited regime, the CVD process is also sensitive to temperature of the substrate. However, a CVD process can operate at high deposition rates—ranging from a few microns/hour to a hundred microns/hour, which is usually highly useful in industrial settings. On the other hand, an ALD process offers several critical advantages over a corresponding CVD process in terms of thin film uniformity, flux independent basis, and therefore independence from substrate size and shape. In addition, the ALD process also provides coatings on sub-micron scale substrate features, and in some cases a lower deposition process temperature that reflects its basis of surface catalytic interaction with the chemical precursors. ALD is, however, beset by lower film deposition rate—which can be an order of magnitude or even lower—as compared to a corresponding CVD process.

Furthermore, in a typical CVD process, two or more reactive gases—chemical precursors—are mixed together and are passed over a heated substrate which is helpful in achieving large area deposition. Such an arrangement is feasible only if the chemical precursors do not exhibit a tendency to pre-react upon mixing. In certain cases, however, if the chemical precursors exhibit strong reactivity towards each other, the gases have to be separated until they reach the substrate surface, but at the same time must be distributed uniformly over the substrate. Such requirements make design and operation of a dual injector CVD reactor rather complex.

In the case of an ALD process, the chemical precursors are sequentially injected into the process volume and the chemical precursors are interspersed with a purge gas. The purge gas, for all practical purposes, is any gas that does not actively participate in the chemical reaction of film deposition. Being flux independent, uniform reactant dispersion is not typically required in an ALD process. Thus simple separation of reactant injectors suffices to set up an ALD process. These advantages allow selection of highly reactive chemical precursors for an ALD process which is something that complicates operation of a CVD process. In fact, precursors that are highly reactive towards each other are purposely sought after or are highly desirable to set up an efficient ALD thin film process.

In a typical ALD method, two or more reactant gases are pulsed sequentially over a heated substrate placed in a process chamber. The reactant gas pulses are separated by a purge gas pulse or two reactant gas pulses are interspersed in a constant flow of a purge gas. Whereas, in a CVD process a heated substrate placed in a process chamber is subjected to simultaneous flow of reactants with an optional flow of a purge gas as a carrier gas.

The prevalent SiC CVD processes largely follow this route. For example, K. Fujihira et al., in Journal of Crystal Growth, vol. 255, pp. 136 (2003), demonstrated high rate CVD process for 4H SiC thin films operating at 1300° C. employing silane (SiH₄) and propane (C₃H₈). Stoldt et al., developed a single precursor, low temperature (800-1000° C.) CVD process for SiC thin films employing 1,3-Disilabutane (SiH₃—CH₂—SiH₂—CH₃) as described in Sensors and Actuators A, vol. 97-98, pp. 410 (2002). Whereas, Sone et al., described a single precursor CVD SiC process employing methyl tri-chlorosilane (MTS: CH₃—SiCl₃) operating at 1300° C., as published in the Journal of Crystal Growth, vol. 219, pp. 245 (2000). It is herein apparent that in general the reaction of deposition of SiC thin films operates at temperatures in excess of 1000° C. It is well known that reactions of deposition of ceramic thin films of BN, B₄C and Si₃N₄ operate in similar temperature range.

The US Patent Application No. 2012/0122302 describes plasma assisted low temperature SiC deposition process using 1,3,5-trisilacyclohexane (C₃Si₃H₁₂) as a precursor operating at 200° C. Thin films of SiC as deposited, however, needed further densification at 600° C. US Patent Application No. 2012/0177841 described a repetitive deposition process employing silicon tetra-chloride SiCl₄ as a silicon source which was reduced by tri-methyl-aluminum [(CH₃)₃AI] with subsequent processing with either plasma or heat treatment at temperatures below 600° C. to reduce H content in the product thin film with composition SiₓC_{y}H_{z} (0<z<16). In the US Patent Application No. 2012/0214318 A1, the inventors described a plasma assisted ALD process employing Di-chloro-tetra-methyl-disilane [Si₂Cl₂(CH₃)₄] and H2 gas at temperatures in the range of 100-400° C. The product film with composition SiC was obtained but was not verified for Si:C ratio. In the process as described in the U.S. Pat. No. RE42,887 the inventors employed di-chloro-silane (Si₂Cl₂) and acetylene (C₂H₂) in hydrogen at temperatures around 900° C. to obtain SiC thin films.

The U.S. Pat. No. 7,901,508 describes use of halogenated hydrocarbons as a chlorine source in conjunction with silane (SiH₄) as silicon source and propane (C₃H₈) as a source for carbon at a substrate temperature of 1600 C.° in the main hydrogen flow. Inclusion of halogenated hydrocarbons were intended to offer operational advantages over addition of HCl (hydrochloric acid) gas in the Si—H—C—CI system that is known to increase the SiC deposition rate by suppressing silicon nucleation at higher temperatures. Silicon nucleation is known to be highly detrimental to the SiC film quality in terms of defect density.

In a case of deposition of BN thin films, BCI₃ in combination with NH₃ gas operating above 1000° C. is a commonly adopted process. A somewhat novel process of BN layer deposition was developed which employed a cyclic integrated chemical precursor s-Triazo-borane (B₃H₃N₃) operating at temperatures of 1000° C. On the other hand, a supposedly super-hard material carbon-nitride (C₃N₄) is recently being deposited using Radio-Frequency (RF) or microwave (MW) plasma with methane (CH₄) and N₂ as a nitrogen source.

As a result of the required high process temperature, selection of substrates for these thin films, though of high commercial and technological value, is rather limited to ceramics, silicon, and quartz. Furthermore, higher process temperatures invariably lead to a number of serious operational disadvantages that often limit commercial applications. In terms of the final product, high operational temperatures lead to high in-film stress, extremely high defect density that severely degrades device performance. Furthermore, inter-diffusion of layers, substrate warping, difficulties in integration with other thin films and impurity inclusion are serious issues of high process temperature. In terms of equipment operation, issues of high power consumption, limits of selection of material of construction of the process chamber and its durability, gas flow stability, chemical precursor consumption and effluent treatment add to the cost and complexity.

Therefore there is a need to develop lowoer temperature CVD and ALD processes for a variety of compositions of ceramic thin films employing elements from the group comprising elements B, N and C, Si, Ge. Thin films with this element set include, but are not limited to, SiC, BN, B₄C, SiCXN_{y}, Si₃N₄, Si_{X}Ge_{(1-X)}, Si_{X}Ge_{(1-X)}C, GeC among others.

### SUMMARY OF THE INVENTION

A method for low temperature deposition of ceramic thin film coatings of carbides, nitrides and mixed phases, the method includes determining deposition chemistries that employ combinations of reactive precursors to affect a required temperature for the deposition of the thin films to a surface of a substrate; loading the substrate into a process chamber; adjusting one or more process parameters including substrate temperature, chamber pressure, and chamber temperature; initiating a deposition cycle; determining whether a predetermined thickness of the thin film coating has been reached, and repeating the deposition cycles until the predetermined thickness has been reached; wherein the deposition is via atomic layer deposition (ALD), nano-layer deposition (NLD), or chemical vapor deposition (CVD); and wherein the combinations of reactive precursors are selected on the basis of reactivity between each of the reactive precursors as determined by the variation of Gibb's free energy (ΔG) with respect to deposition temperature in the chamber.

The method includes deposition of thin films of boron (B) carbides, nitrogen (N), nitrides, carbo-nitrides of silicon (Si), carbon (C), germanium (Ge), phosphorus (P), arsenic (As), oxygen (O), sulfur (S), and selenium (S). A higher negative value of Gibb's free energy of reaction forms the basis for selection of the reactive precursor combinations.

### BRIEF DESCRIPTION OF THE DRAWINGS

FIG. 1A illustrates a substrate with surface —OH groups formed due to chemisorbed water from the ambient, while other molecules such as CO and CO₂ do not strongly bond with the surface and only physiosorbed;

FIG. 1B illustrates the exchange of Cl with surface H from chemisorptions of TiCl₄ and formation of O—Ti bond;

FIG. 1C shows the reaction of chemisorbed —TiCl₃ with water (H₂O) molecule to form TiO₂ during an ALD process;

FIG. 2A describes a typical ALD cycle with two reactive precursor pulses interspersed with two purge gas pulses;

FIG. 2B represents a variation of the ALD cycle with two reactive precursor pulses spaced in a constant flow of a purge gas in the process chamber;

FIG. 2C illustrates variation of various process gas flow parameters in a typical CVD process;

FIG. 3 is a flowchart of a typical ALD process sequence to build a thin film of desired thickness;

FIG. 4 is a flowchart illustrating the variation of deposition system parameters in a typical CVD process;

FIG. 5A illustrates a substrate for deposition with surface adsorbed —OH groups according to an embodiment of the invention;

FIG. 5B illustrates chemisorption of a CCl₄ molecule in gas phase with the surface —OH group and bond formation with release of HCl molecule in the gas phase according to an embodiment of the invention;

FIG. 5C demonstrates the reaction of silane (SiH₄) molecule on the surface with pre-chemisorbed —CCl₃ species, exchange reaction with formation of Si—C bond and release of HCl and surface terminated with H atoms according to an embodiment of the invention;

FIG. 5D illustrates the first step of the next ALD cycle starting with chemisorption of CCl₄ on H terminated surface with bond formation between Si and C according to an embodiment of the invention;

FIG. 6A is a graph of the variation of Gibb's Free Energy (ΔG) vs. substrate temperature for reaction of formation of SiC with SiH₄ and CCl₄ as precursors for Si and C respectively according to an embodiment of the invention; and

FIG. 6B is a graph of the variation of Gibb's Free Energy (ΔG) vs. substrate temperature for reaction of formation of BN with B₂H6 and NF₃ as precursors for B and N respectively according to an embodiment of the invention.

### DESCRIPTION OF THE INVENTION

An inventive method is provided for low temperature deposition of ceramic thin films of carbides, nitrides and mixed phases such as carbo-nitrides by atomic layer deposition (ALD), nano-layer deposition (NLD), and chemical vapor deposition (CVD). The deposition chemistries employ combinations of precursors to affect the thin film processes at substantially lower temperatures than current deposition processes for the deposition of thin films of boron (B), carbides, nitrogen (N), nitrides, carbo-nitrides of silicon (Si), carbon (C), germanium (Ge), phosphorus (P), arsenic (As), oxygen (O), sulfur (S), and selenium (S) on various substrates at substantially lower temperatures than existing thin film deposition methods. Deposition temperatures in embodiments of the inventive method are preferably below 600° C., whereas existing deposition processes are conducted at higher temperatures. Embodiments of the inventive ALD and corresponding NLD and CVD processes or methods provide lower temperature deposition of various thin films comprising elements from the group B, C, Si, Ge, N, P, As and O, S and Se.

The reactive precursor combinations in embodiments of the inventive deposition method are selected on the basis of reactivity towards one another as determined by the variation of Gibb's free energy (ΔG) with respect to deposition temperature. Higher negative value of Gibb's free energy of reaction forms the basis for selection of preferred reactive precursor combinations.

For the ALD and CVD processes, the reactive precursors of various elements are generally categorized according to one type e.g., either hydride or halide. Whereas, compounds comprising hydrogen and halogen attached to C and Si form another category. The thin film deposition processes of various materials are embodied based on one type of gases—e.g., hydride of one element is reacted with halide of the second element to affect a vigorous reaction of deposition such that the net Gibb's free energy of reaction (ΔG) is negative. Moreover, in case of a ternary or quaternary thin film, hydrides of one or more elements are combined with the halides of the other desired elements. Accordingly for the inventive ALD processes one or more hydrides of elements from the group comprising B, C, N, Si, Ge, P, O, S, and Se are selected as the first reactive precursor and one or more halides of F, Cl, Br, or I are selected as the second reactive precursor. For example, nitrogen tri-fluoride (NF₃) is employed as a nitrogen source in combination with B₂H₆ as a boron precursor. Whereas, in case of silicon carbide ALD process, silicon source is selected from Si₂H₆, SiH₄, SiH₃X, SiH₂X₂ and SiHX₃ (where X=F, Cl, Br and I) and carbon source is selected from CX₄, CX₃H, CX₂H₂, CX₃H (where X=F, Cl, Br and I).

Furthermore, mixed halocarbons such as chloro-fluoro-carbons with general formula CₙXₐZ_{b} (where, n, a, b are integers and X and Z are halogens) are also equally suitable as carbon sources in the development of ALD, NLD and CVD processes. Another sub-class of reactive precursors include mix-halides of C and Si denoted by a general formula MₙHₐX_{b} (M=C and Si; X=F, Cl, Br, I and n, a, b are integers). The preferred embodiments describe various combinations of the reactive precursors that are employed to develop a variety of thin film processes.

However, it is noted that in regard to the ALD thin film process development, the first reactive precursor may be either a halide or a hydride and the corresponding second reactive precursor is then a hydride or a halide. For the corresponding CVD processes of various materials such as carbides, nitrides, silicides, sulfides, selenides, phosphides, arsenides and mixed phases thereof, the same reactant combination as used in the ALD process is employed to obtain desired thin film composition.

In order to implement embodiments of the inventive method, a variety of CVD reactor designs prevalent in the industry that separately and uniformly inject two reactive reactants are employed. One such ALD/CVD reactor and its various configurations are described in the U.S. Pat. No. 6,812,157 which is included herein in its entirety by way of reference.

In order to implement the deposition processes of the invention a process chamber that has the capability to vary and control process variables to perform the desired chemical reactions is required. The process chamber is provided with a heated platen such that the temperature can be adjusted and maintained constant according to the requirements of a particular deposition process. The substrate on to which a desired thin film is to be deposited is placed in thermal contact to a heated platen to heat the substrate to a pre-determined temperature to affect the desired chemical reaction. The process chamber is further provided with gas inlets that are connected to a precursor gas supply through appropriate flow measurements and control valves. The process chamber is also connected to a vacuum pump through a downstream throttle valve to adjust chamber pressure during the deposition process. The process chamber pressure can be either held constant with the help of a constantly adjusting downstream throttle valve in-sync with incoming gas pulses, or the pressure can be allowed to dynamically vary with gas pulsing with a fixed position of a throttle valve.

Thin film deposition processes described in the present invention largely fall into atomic layer deposition (ALD) and chemical vapor deposition (CVD) in nature. In a typical ALD process the precursors are sequentially injected in to the process chamber with either a continuous background flow of a purge gas or the reactive precursors are interspersed by two purge gas pulses to include an ALD cycle which is repeated to build the desired film thickness. The fundamentals of an ALD process and its operation are as described in the U.S. Pat. No. 4,058,430. In the case of a Chemical Vapor Deposition (CVD) process the all the reactive precursor gases along with a purge gas (mainly used as a diluents or ballast gas) are simultaneously passed at a constant rate over a heated substrate wherein the chamber pressure or and/or substrate temperature may be adjusted as required.

An intermediate form of thin film deposition called Nano-Layer Deposition (NLD) has been prevalent recently in which one or both purge gas pulses are omitted from the process sequence formulation. In an NLD process, the reactive gases are usually pulsed alternatively in succession. As a result, the reactive precursor molecules form a chemical bond with the underlying species. However, the excess reactive precursor molecules are not swept away from the vicinity of the substrate surface, and as a result more than a mono-layer film is formed in one pair of gas pulses. It is to be understood that the NLD process is also under the ambit of this invention whereupon the film deposition chemistry is based on the proper selection and combination of reactive precursors s disclosed herein.

Furthermore, the processes described herein—ALD, CVD or NLD—can be effectively performed at atmospheric pressure (760 Torr) as well as at a chamber pressure as low as few milli-Torr (mT). So also, the process temperature can vary from one ALD or CVD process to the other as it largely depends on various factors such reactive precursor combination, substrate type and so on. It is therefore necessary to note that the applicable process temperature regime is significantly wide-ranging from room temperature to 1,000° C.

The ALD process prefers selection of precursors that are highly reactive towards each other for its effective operation. However, it is imperative to note that same reactive precursor combination can also be employed to develop a Corresponding CVD process with the same combination of reactive precursors, provided sufficient care is taken to effectively separate and also uniformly distribute both the precursor flows until they reach the substrate surface to avert undesirable pre-reaction and particulate formation with the help of proper process chamber designs. Interaction of substrate surface with the reactive precursor is of critical importance in an ALD process. Therefore, the nature of a reactive precursor molecule in terms of its geometry, size, and the stereo specificity of the peripheral reactive groups are of highly significant value to realize an efficient ALD process with excellent surface coverage, high film density and overall film quality.

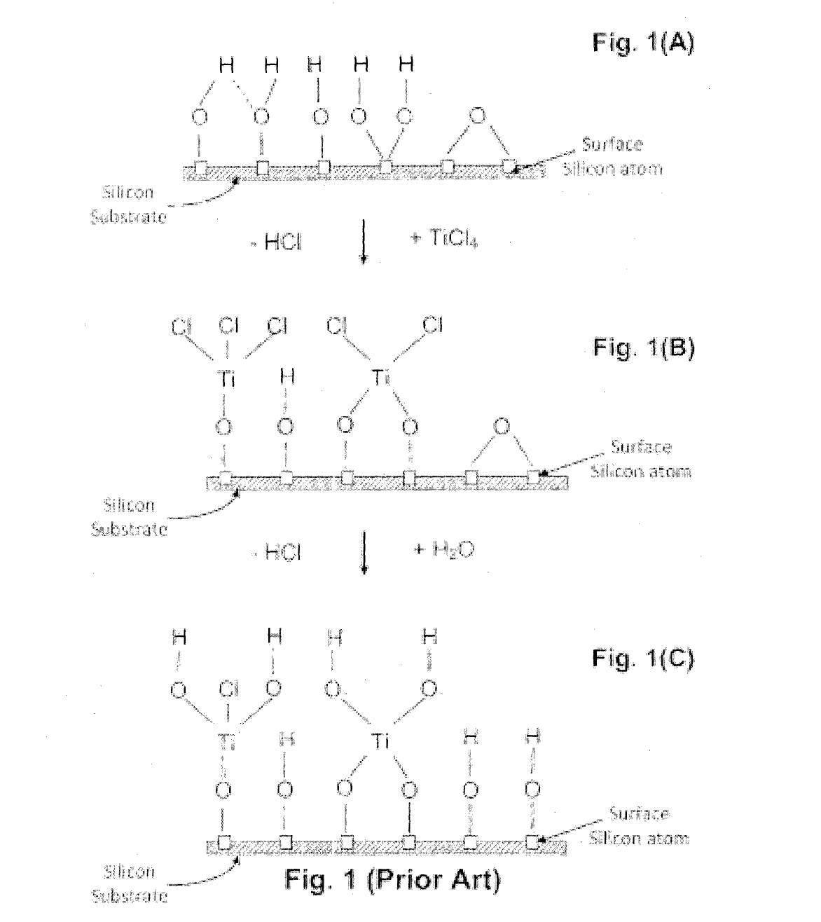

Typically, the ALD process is highly surface sensitive such that the chemical precursor molecules injected into the chamber above the substrate in the gas phase react with the pre-adsorbed surface species—in an ambient—these species are typically moisture (H₂O) and CO and CO₂ and N₂ gas. It is, however, noteworthy that of these four gaseous species present in the ambient, it is the H₂O molecule that shows a strong propensity to react with the surface atoms—metals or non-metals, and thus a surface terminated with OH groups is readily present as shown in FIG. 1A. This surface nature and thus its reactivity can be altered by treating the surface by an appropriate gaseous plasma, high temperature or high vacuum or by a combination thereof.

An incoming gaseous precursor molecule e.g., TiCl₄ which is highly reactive towards the surface —OH groups thus chemisorbs by exchanging CI atom with the surface to form a chemical bond between the surface 0 species and —TiCl₃. During the chemisorptions process an HCl molecule is released as shown in FIG. 1B. In the next step, an incoming H₂O molecule in the gas phase chemisorbs on the Cl groups of —TiCl₃ group and Ti—O bond is formed as shown in FIG. 1C. In this step, the surface terminates with —OH groups which are receptive to the next pulse of TiCl₄ gaseous precursor. The gas pulsing sequence as described above does not describe purge gas pulses that follow both TiCl₄ and H₂O pulses. The main purpose of purge gas pulses is to sweep away excess TiCl₄ and/or H₂O molecules that are physiosorbed or loosely attached to the substrate. From the foregoing discussion, it is amply clear that for an efficient ALD process it is essential to select the chemical precursors that are highly reactive towards each other. Flux independent chemisorption based ALD processes are advantageous since it considerably simplifies process chamber design and the chamber operation. It, however, places a significant emphasis and importance on the chemical nature of the substrate surface to receive (anchor) the first reactive chemical precursor molecule and initiate the ALD cycle to obtain a desired product.

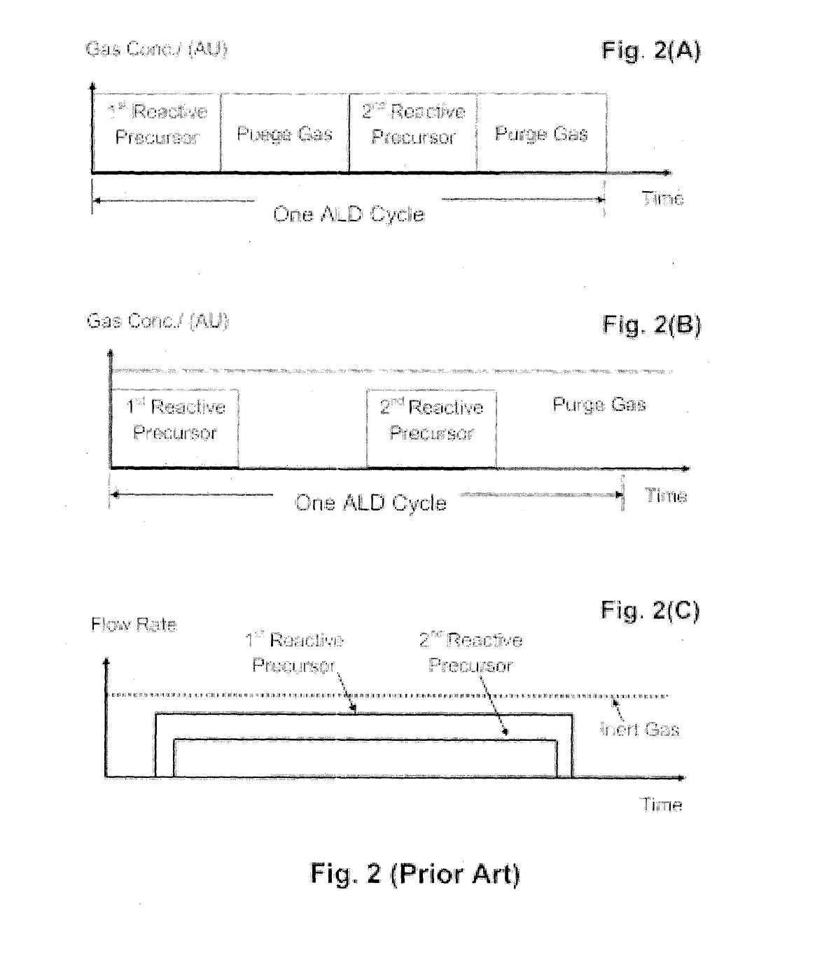

The process sequence of FIGS. 1A-1C illustrates one ALD cycle with four discrete pulses—first reactive gas, purge gas, second reactive gas, and lastly a purge gas as shown in FIG. 2A, which is then repeated to build desired thin film thickness. Alternatively, the purge gas flow is maintained constant in the chamber and the reactive gas pulses are interspersed in time as shown in FIG. 2B in an ALD cycle which is then repeated to build the desired film thickness. Formation of bonds with surface species during a reactive precursor pulse over the substrate in an ALD process thus calls for chemical precursors that are highly reactive towards one another. However, for a Chemical Vapor Deposition (CVD) process, all the precursor gases along with a purge gas (mainly used as a diluents or ballast gas) are simultaneously passed at a constant rate over a heated substrate wherein chamber pressure and/or substrate temperature may be modulated. Variation of reactive precursor and inert/purge gas flow sequencing with time (at constant temperature and pressure) in a typical CVD process is as shown in FIG. 2C.

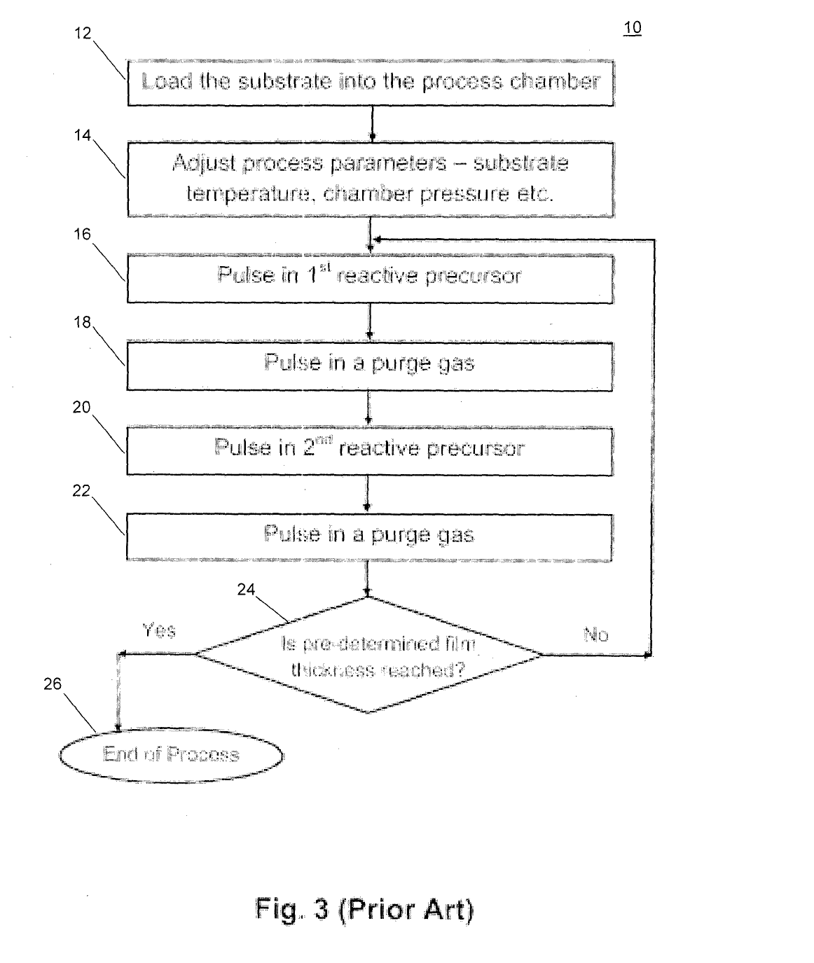

FIG. 3 describes a logical flow diagram of a typical ALD process sequence 10 with four discrete pulses. The process starts with the loading of a substrate into a process chamber 12 and adjusting process parameters including substrate temperature, chamber pressure, etc. 14. Subsequently, an ALD cycle is started with a pulse of a first reactive precursor gas 16, then a pulse of purge gas 18, a pulse of a second reactive cursor 20, and then a pulse of purge gas 22 are introduced into the chamber. A determination is then made if a pre-determined film thickness of a deposited coating on the substrate has been reached 24. If the predetermined thickness of coating has been reached, the process ends 26. However, if the coating thickness on the substrate has not been reached, the ALD cycle of pulses of gases in sequence 16-22 is repeated until the pre-determined film thickness is reached.

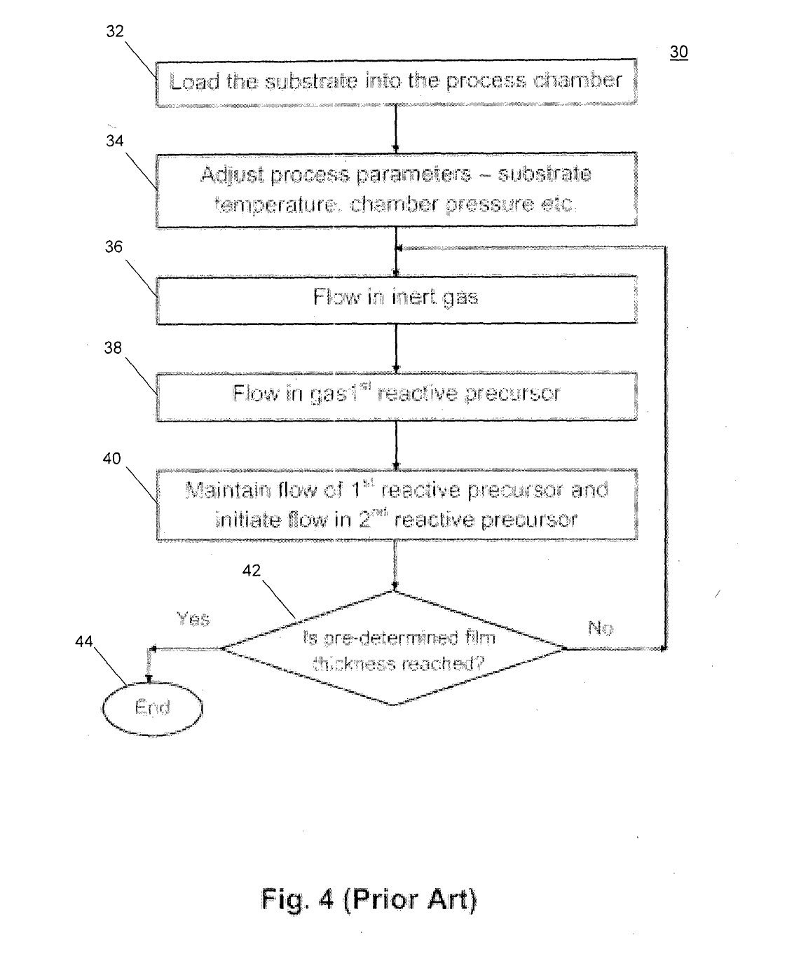

FIG. 4 illustrates a logical flow diagram of a typical CVD process 30. The process starts with the loading of a substrate into a process chamber 32 and adjusting process parameters including substrate temperature, chamber pressure, etc. 44. Subsequently, a CVD cycle is started with the introduction of an inert gas into the chamber 36, followed by a flow of a first reactive precursor gas 38, and subsequently initiating the flow of a second precursor gas while maintaining the flow of the first precursor gas 40 into the chamber. A determination is then made if a pre-determined film thickness of a deposited coating on the substrate has been reached 42. If the predetermined thickness of coating has been reached, the process ends 44. However, if the coating thickness on the substrate has not been reached, the CVD cycle of pulses of gases in sequence 36-40 is repeated until the pre-determined thickness is reached.

In embodiments of the inventive deposition process, halides of elements comprising B, C, Si, Ge, N, P, As, S and Se are selected as a group of first reactive precursors to obtain desired thin films by employing ALD, NLD and CVD processes. The second reactive precursors for the ALD, NLD and CVD processes are selected from hydrides of elements comprising B, C, Si, Ge, N, P, As, O, S and Se. Thus the representative compounds of these elements are selected from the group comprising, but not limited to, B₂H₆, CH₄, SiH₄, Si₂H₆, NH₃, N₂H₄, PH₃, AsH₃, H₂O, H₂S and H₂Se. Another sub-class of reactive precursors comprising C and Si are also included such that mixed halides denoted by a general formula CₙX′ₐX″_{b} (X=F, Cl, Br and I; n, a and b are each integers). Yet another sub-class of reactive precursors include compounds of mix-halides of C and Si denoted by a general formula MₙHₐX_{b} (M=C and Si; X=F, Cl, Br, I and n, a, b are integers). The preferred embodiments describe various combinations of the reactive precursors that are employed to develop a variety of thin film processes.

Embodiments of the invention are further explained with the help the examples and the associated Figures as described below.

### Example 1

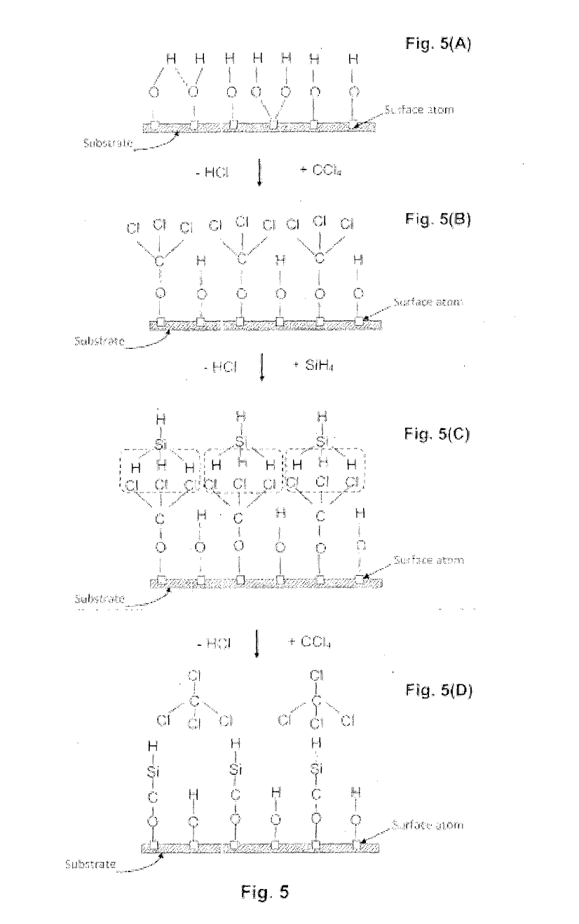

Deposition of silicon carbide (SiC) films by ALD, NLD and CVD processes: As described in the background section of the invention, SiC is an important industrial ceramic with numerous applications. However, the prevalent thin film deposition processes for SiC operates at temperatures in excess of 1000° C. Therefore, a low temperature ALD and also CVD SiC thin film process is thus highly desirable. Referring to FIG. 5A, the surface of a substrate is terminated with —OH groups which are highly receptive and reactive towards Cl atoms. Next in FIG. 5B wherein chemisorption of a carbon tetrachloride (CCl₄) molecule (similar to a TiCl₄ molecule as described in FIG. 1B) on to the —OH terminated substrate surface with the formation of HCl as a product that is released in the gas phase is completed. The substrate, at the end of CCl₄ chemisorption step, is terminated with Cl groups with formation of a M-0-CCl3 (M: surface atom of the substrate, denoted by a square in FIGS. 5A, B, C and D) linkage. Next a pulse of a purge gas (not shown in the drawings) is introduced in to the process which swipes away excess CCl₄ molecules in the vicinity of the substrate. Subsequently, a pulse of silane (SiH₄) gas is introduced into the process chamber. The silane gas molecules react with the chemisorbed —O—CCl₃ groups vigorously under the process conditions and forms Si—C bond with elimination of HCl molecules as shown in FIG. 5C. A purge gas pulse is employed to remove excess SiH₄ molecules (not shown in the scheme). The surface terminates with H atoms and is thus receptive to the next incoming CCl₄ pulse as shown in FIG. 5D. The overall reaction of SiC deposition is as follows:

CCl₄+SiH₄→SiC+4HCl eq. (1)

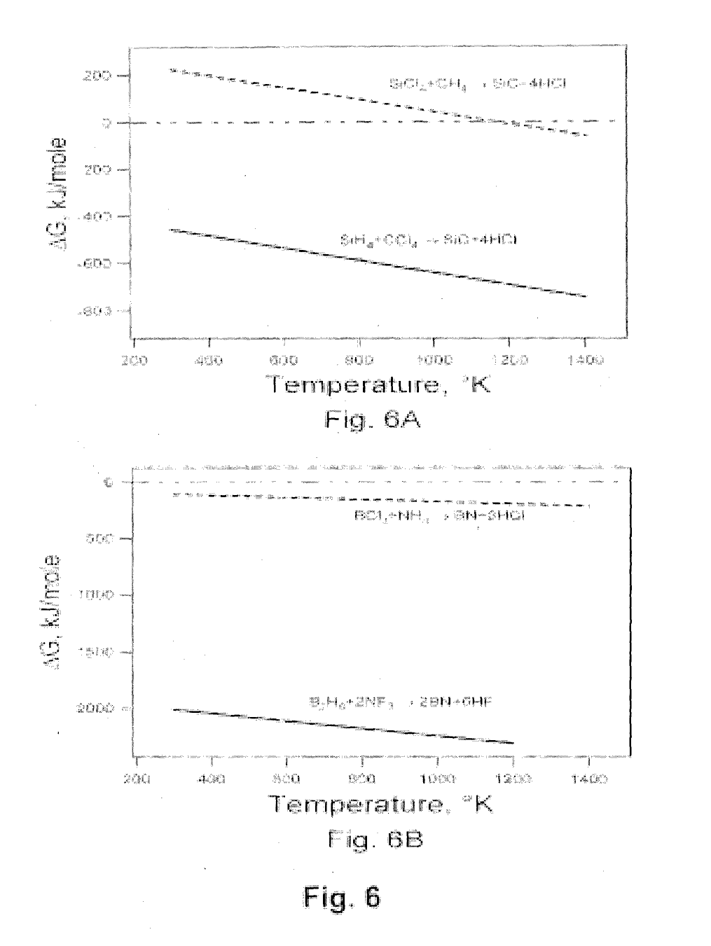

FIG. 6A illustrates the variation of Gibb's Free Energy (ΔG) vs. Temperature for the reaction as shown in eq. (1) and its comparison with the conventional SiC CVD process. High negative value of ΔG in FIG. 6A with respect to process temperature (even at room temperature) illustrates very high potential for feasibility of a lower temperature SiC deposition process (ALD or CVD) as described in eq. (1).

It is understood that the SiC ALD process as described above is not limited by the process chamber pressure such that it can be performed over a wide range of chamber pressure values that range from a few mT to 760 Torr (1 atmosphere) and even above. Moreover, the SiC ALD process can also be performed over a wide temperature range—for example from room temperature to 1000° C. Moreover, the deposition chemistry as described in eq. (1) is equally applicable to a corresponding CVD and NLD process.

### Example 2

Another thin film material of industrial value is boron nitride (BN). Thin films of BN are currently being deposited employing BCl₃ and ammonia (NH₃) at high temperature ranging from 700-1000° C. and above. FIG. 6B illustrates variation of Gibb's Free Energy (ΔG) vs. temperature for the following chemical reaction:

B₂H₆+2NF₃→2BN+6HF eq. (2)

The Very high value of ΔG vs. temperature of the reaction in equation (2) in comparison with the conventional BN process (ALD or CVD) illustrates the high value for developing a low temperature BN thin deposition process. The BN deposition process can be performed at pressures ranging from a few mT to 760 Torr and in the temperature range of 20° C. to 1000° C.

### Example 3

Deposition of C₃N₄ thin films: Processes of deposition and various applications of C₃N₄ as a thin film material have not yet been fully explored. It is expected to be one of the super-hard materials known. The formation of C₃N₄ films by ALD, NLD or CVD processes proceeds through carbon halide (e.g. CF₄, CF₂Cl₂, or CCl₄) as a carbon source, and NH₃ as a nitrogen source in the temperature range of 20° C. to 1000° C., and in a pressure range of a few mT to 760 Torr. The overall chemical reaction of deposition (with CCl₄ as a C source) is as follows:

3CF₄+4NH₃→C₃N₄+12HF eq. (3)

### Example 4

Deposition of Si₃N₄ films: Silicon nitride is an important industrial ceramic due to the fact that it is corrosion and wear resistant material with excellent optical properties. Applications of silicon nitride are in ball-bearing coatings as well as in electrical insulators, anti-reflection coatings and so on. Formation of thin films of Si₃N₄ proceeds in an ALD, NLD or CVD process, by employing silane (SiH₄) as a silicon source and NF₃ as a nitrogen source. The overall chemical reaction of Si₃N₄ deposition is as follows:

3SiH₄+4NF₃→Si₃N₄+12HF eq. (4)

### Example 5

Deposition of SiXGe(1_X) films: Thin films of SiXGe(1_X) can be deposited by ALD, NLD or CVD method by employing a hydride source of Si and a halide source of Ge. The first reactive gas pulse includes a mixture of SiCl₄ and GeCl₄ in a fixed ratio of a:b to form a first monolayer comprising Si and Ge atoms terminated with Cl groups. The second reactive gas pulse includes a mixture of GeH₄ and SiH₄ in the ratio of a:b and a fixed value of x can be obtained. The overall reaction of SiXGe(1_X) deposition process can be written as (without balancing the equation):

(SiCl₄+GeCl₄)+(SiH₄+GeH₄)→SiXGe(1_X)+HCl eq. (5)

Parentheses denote the pulse group. An alternative method to modulate the Si:Ge ratio is by employing either silane or germane gas exclusively as a second reactive precursor. The ALD process reactions are as follows:

(SiCl₄+GeCl₄)+(SiH₄)→SiXGe(1_X)+HCl eq. (6)

The process as described in eq. (6) leads to silicon rich (higher value of x) phase. On the other hand, employing GeH₄ as a second reactive precursor leads to a Ge rich phase as described in eq. (7):

(SiCl₄+GeCl₄)+(GeH₄)→SiXGe(1_X)+HCl eq. (7)

Moreover, the ratio of Si:Ge in the film SiXGe(1_X) (value of x) can also be varied by varying the process conditions such as substrate temperature and pulse width etc.

### Example 6

Deposition of ternary films of various materials such as SiCXN_{y}, in an ALD, NLD or CVD processes proceeds by employing SiH₄ as a first reactive gas pulse in combination with CCl₄ (alternatively CF₄ is equally effective) and NF₃ mixture in the second reactive gas pulse.

(SiH₄)+(CCl₄+NF₃)→SiCXN_{y}+HCl eq. (8)

### Example 7

Quaternary thin films can be deposited in ALD, NLD or CVD mode by employing a mixture of hydrides in the first pulse and a mixture of halides in the second pulse. For example, thin films of SiCXB_{y}NZ can be deposited by using first reactive precursor gas mixture comprising silane (SiH₄) and di-borane (B₂H₆) and the second reactive precursor gas mixture comprising carbon tetra-chloride (CCl₄) and nitrogen tri-fluoride (NF₃) with the overall chemical reaction as given in eq. (9)

(SiH₄+B₂H₆)+(CCl₄+NF₃)→SiCXB_{y}NZ+HCl+HF eq. (9)

### Example 8

Carbon thin films: ALD, NLD or CVD processes of thin films comprising carbon proceed by employing various reactive precursor combinations. The foremost reactive precursor combination is pulsing of di-chloro-halogen with general formula (CH₂X₂, X=F, Cl, Br and I) as shown in eq. 10.

CH₂X₂+CH₂X₂→C+2HX eq. (10)

Alternatively, CX₄ (X=F, Cl, Br and I) as the first reactive precursor and CH₄ as the second reactive precursor are equally suitable to deposit carbon thin films with the overall chemical reaction as shown in eq. (11)

CX₄+CH₄→C+4HX eq. (11)

### Example 9

Reduction of halocarbons with hydro-silanes and boranes to form mono-layer of carbon: Silane (SiH₄) and di-silane (Si₂H₆) are known to used as reducing agents in ALD processes for deposition of metals such as tungsten in a temperature range of 200-400 degree C., through a following reaction:

WF₆+SiH₄→W+SiF₄+2HF+H₂ eq. (12)

WF₆+Si₂H₆→W+2SiHF₃+2H₂ eq. (13)

### REFERENCES

(a) J. W. Elam, C. E. Nelson, R. K. Grubbs and S. M. George: Thin Solid Films, volume 386, pp. 41 (2001).
(b) Journal of Vacuum Science & Technology (B), Volume 22, No. 4, pp. 1811-1821 July 2004.

Accordingly, CCl₄ can be reduced to deposit thin films of carbon in various forms for example, amorphous and/or grapheme in the temperature range of 200-800 degrees C. The overall reactions can be summarized as:

CCl₄+SiH₄→C+SiCl₄+2H₂ eq. (14)

CCl₄+SiH₄→C+SiH₂Cl₂+2HCl eq. (15)

CCl₄+Si₂H₆→C+Si₂H2Cl₄+3H₂ eq. (16)

The overall reaction of deposition of carbon or grapheme films can also be facilitated by using di-borane (B₂H₆) as a reducing agent in lieu of di-silane.

The foregoing description is illustrative of particular embodiments of the invention, but is not meant to be a limitation upon the practice thereof. The following claims, including all equivalents thereof, are intended to define the scope of the invention.

1. A method for low temperature deposition of ceramic thin film coatings of carbides, nitrides and mixed phases, said method comprising:
determining deposition chemistries that employ combinations of reactive precursors to affect a required temperature for the deposition of said thin films to a surface of a substrate;
loading said substrate into a process chamber;
adjusting one or more process parameters comprising substrate temperature, chamber pressure, and chamber temperature;
initiating a deposition cycle;
determining whether a predetermined thickness of said thin film coating has been reached, and repeating said deposition cycles until said predetermined thickness has been reached;
wherein said deposition is via atomic layer deposition (ALD), nano-layer deposition (NLD), or chemical vapor deposition (CVD);
wherein said combinations of reactive precursors are selected on the basis of reactivity between each of said reactive precursors as determined by the variation of Gibb's free energy (ΔG) with respect to deposition temperature in said chamber.

2. The method of claim 1 wherein said thin films comprise boron (B) carbides, nitrogen (N), nitrides, carbo-nitrides of silicon (Si), carbon (C), germanium (Ge), phosphorus (P), arsenic (As), oxygen (O), sulfur (S), and selenium (Se).

3. The method of claim 1 wherein a higher negative value of Gibb's free energy of reaction forms the basis for selection of said reactive precursor combinations.

4. The method of claim 1 wherein for said ALD and said CVD processes, the reactive precursors of various elements are generally categorized according to either hydride or halide.

5. The method of claim 4 wherein a first element from said hydride is reacted with halide a second element from said halide to affect a vigorous reaction of deposition such that the net Gibb's free energy of reaction (ΔG) is negative.

6. The method of claim 5 wherein said first element is selected form a group of hydrides comprising B, C, N, Si, Ge, P, O, As, S, and Se; and
wherein said second element is selected from a group of halides comprising F, Cl, Br, or I.

7. The method of claim 6 wherein a nitrogen tri-fluoride (NF₃) is employed as a nitrogen source in combination with a B₂H₆ as a boron precursor.

8. The method of claim 6 wherein said ALD process is a silicon chloride based process with a silicon source selected from Si₂H₆, SiH₄, SiH₃X, SiH₂X₂ and SiHX₃ where X in each occurrence is independently F, Cl, Br or I; and carbon source is selected from CX₄, CX₃H, CX₂H₂, CX₃H where X in each occurrence is independently F, Cl, Br or I.

9. The method of claim 6 wherein mixed halocarbons are a source of carbon.

10. The method of claim 9 wherein said mixed halocarbon is a chloro-fluoro-carbon with general formula CₙXₐZ_{b}, where, n, a, b are integers and X and Z are halogens.

11. The method of claim 6 wherein said halides further comprise a sub-class of mix-halides of C and Si denoted by a general formula MₙHₐX_{b}, where M=C and Si; X in each occurrence is independently F, Cl, Br, or I; and n, a, b are integers.

12. The method of claim 1 wherein said chamber pressure ranges between atmospheric pressure (760 Torr) to as low as 1 milli-Torr (mT).

13. The method of claim 1 said method further comprising depositing silicon carbide films by terminating said surface of said substrate with —OH groups which are highly receptive and reactive towards Cl atoms;
introducing carbon tetra-chloride (CCl₄) molecules for chemisorption onto the —OH terminated substrate surface to form O—CCl₃ groups;
pulsing a purge gas into said chamber to sweeps away excess CCl₄ molecules in the vicinity of said substrate;
pulsing silane (SiH₄) gas is introduced into said process chamber to react with said chemisorbed —O—CCl₃ groups to form Si—C bonds;
pulsing said purge gas to remove excess SiH₄ molecules leaving said surface with hydrogen (H) terminations that are receptive to an incoming CCl₄ pulse; and
wherein the overall reaction of said SiC deposition is CCl₄+SiH₄→SiC+4 HCl.

14. A film produced by the method of claim 1.
